(19) United States
(12) Patent Application Publication
(10) Pub. No.: US 2007/0105260 A1
(43) Pub. Date: May 10, 2007

(54) Nitride-based semiconductor device and production method thereof

(75) Inventor: Mayuko Fudeta, Mihara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/595,064

(22) Filed: Nov. 8, 2006

(30) Foreign Application Priority Data
Nov. 8, 2005 (JP) 2005-323504

(51) Int. Cl. H01L 21/00; H01L 33/00; H01L 21/4763

(52) U.S. Cl. 438/46; 438/640; 257/79

(57) ABSTRACT

A method of producing a nitride-based semiconductor device includes the steps of forming a releasing layer on a substrate for facilitating separation of the substrate; and forming at least one nitride-based semiconductor layer on the releasing layer. As the releasing layer, or in place of the releasing layer, at least one conductive film may be formed on the substrate.

This nonprovisional application is based on Japanese Patent Application No. 2005-323504 filed with the Japan Patent Office on Nov. 8, 2005, the entire contents of which are hereby incorporated by reference.

### BACKGROUND OF THE INVENTION

1. Field of the Invention

The present invention relates to a semiconductor device including a layer of nitride-based compound semiconductor (InₓAl_{y}Ga_{1-x-y}N: 0≦x, 0≦y, x+y<1) and to improvement in a method of producing the same.

2. Description of the Background Art

Japanese Patent Laying-Open No. 06-196757 discloses a method of forming a nitride-based semiconductor device that can be used for a blue-light-emitting diode or a blue laser diode. According to the disclosure of Japanese Patent Laying-Open No. 06-196757, a GaN buffer layer is grown to a thickness of about 20 nm on a sapphire substrate at a temperature of 510° C. On the GaN buffer layer, a GaN layer is grown to a thickness of 2 μm at a substrate temperature of 1030° C. Further, on the GaN layer, an InGaN light-emitting layer is grown at a substrate temperature of 800° C.

Japanese Patent Laying-Open No. 2000-277804 discloses a technique of laminating a conductive substrate on a nitride-based semiconductor stacked-layer structure formed on a sapphire substrate and thereafter removing the sapphire substrate by lapping or the like.

There are some problems in the nitride-based semiconductor light-emitting device produced by the prior art as disclosed in Japanese Patent Laying-Open No. 06-196757.

The most important problem is that threading dislocation density is significantly increased in a plurality of nitride-based semiconductor layers formed on the sapphire substrate. The reason why the threading dislocation density increases is as follows. Since the buffer layer is formed at a relatively low temperature on the sapphire substrate and then the GaN layer is grown at a temperature increased by as much as 500° C. or more, atoms on the surface of buffer layer evaporates again in the course of temperature increase, causing a large number of defects. As a result, a large number of threading dislocations are generated in the GaN layer grown afterwards. This leads to poor characteristics of a resulting light-emitting device.

Another problem in the prior art is that an electrode cannot be formed on the back surface of the sapphire substrate, as the sapphire substrate is an insulator. This leads to a larger chip size and a higher cost of the light-emitting device. Further, the sapphire substrate is very hard, and it is difficult to divide the substrate into chips. This leads to a lower yield rate of the light-emitting devices.

In order to solve these problems, Japanese Patent Laying-Open No. 2000-277804 discloses a method as follows. A conductive substrate is laminated on a nitride-based semiconductor stacked-layer structure formed on a sapphire substrate, and then the sapphire substrate is removed by lapping. Thereafter, upper and lower electrodes are formed so that the chip size can be reduced. In this case, an Si substrate or the like that is easy to be divided is used as the conductive substrate so that chip division can be facilitated. Actually, however, it is very difficult to remove the sapphire substrate by lapping and this causes a lower yield rate of the light-emitting devices.

The reason for this resides in that a wafer having a nitride-based semiconductor stacked-layer structure grown on a sapphire substrate warps because of difference in thermal expansion coefficient between the nitride-based semiconductor and sapphire. The warp is as large as about several tens microns in level difference between the center and an edge of the wafer, though it depends on the thickness of the nitride-based semiconductor stacked-layer structure and on others. Since the thickness of nitride-based semiconductor stacked-layer structure is a few microns, uniform lapping for removing the substrate is possible only when the warp of the wafer is suppressed to the order of sub-microns. Otherwise, there will be formed a part where the nitride-based semiconductor layer is exposed and a part where the sapphire substrate remains. Although Japanese Patent Laying-Open No. 2000-277804 discloses use of etching in addition to lapping in order to solve this problem, an etchant that can etch sapphire is hardly available and the etching rate is very slow. Therefore, such an approach is impractical for actual production. Further, the sapphire cannot selectively be etched by dry etching and it is difficult to produce a light-emitting device having upper and lower electrodes by the conventional method.

Further, in the light-emitting device having upper and lower electrodes produced through the conventional method, the electrode formed on the surface exposed by removing the sapphire substrate has high contact resistance, leading to increased driving voltage and hence larger power consumption.

Furthermore, according to the conventional method of Japanese Patent Laying-Open No. 06-196757, the sapphire substrate is transparent and thus considerable part of light generated in the light-emitting layer of the light-emitting device passes through the substrate and light is also emitted from the side surfaces of sapphire substrate, whereby causing decrease in axial luminous intensity of the light-emitting device. The nitride-based semiconductor light-emitting device is often used as a back light for a display, and what is important for such an application is not the amount of light emitted from the chip as a whole but the amount of light emitted from the front surface of the chip. Therefore, it is desirable to increase axial luminous intensity of the light-emitting device.

### SUMMARY OF THE INVENTION

In view of the problems in the prior art as described above, the present invention aims to improve various characteristics of the nitride-based semiconductor device and to improve the yield rate of the device.

According to an aspect of the present invention, a method of producing a nitride-based semiconductor device includes the steps of forming a releasing layer on a substrate, which can facilitate later separation of the substrate, and forming at least one nitride-based semiconductor layer on the releasing layer. Further, according to another aspect of the present invention, a method of producing a nitride-based semiconductor device includes the steps of forming at least one conductive film on a substrate; and forming at least one nitride-based semiconductor layer on the conductive layer.

The conductive film may include any of a metal, a metalloid, an alloy or a semiconductor. Specifically, the conductive film may include any of Mo, W, Ta, Nd, Al, Ti, Hf, Si, Ge, GaAs and GaP. In the case that the conductive film is desired to have a reflectance of at least 50%, it may include a metal or an alloy containing Ag or Al. The conductive film may also be a conductive metal oxide, and in that case, the conductive metal oxide may include indium oxide. Further, the conductive film may have a multi-layered structure. The conductive film can be formed by an evaporation method, a sputtering method or a plasma CVD method.

In the step of forming at least one nitride-based semiconductor layer, a nitride-based semiconductor underlying layer, a nitride-based semiconductor layer of a first conductivity type, a light-emitting layer, and a nitride-based semiconductor layer of a second conductivity type may be deposited successively. Preferably, the nitride-based semiconductor underlying layer is deposited at a temperature of at least 900° C. Preferably, the nitride-based semiconductor layer of the first conductivity type is deposited at a temperature not higher than the deposition temperature of the nitride-based semiconductor underlying layer. The metal layer contained in the conductive film may be reacted to form a nitride film, and the nitride film may be processed to a shape of a current blocking layer. The nitride-based semiconductor underlying layer can be formed of InₓAl_{y}Ga_{1-x-y}N (0≦x, 0≦y, x+y<1).

The conductive film may include an Mo layer, and the Mo layer can be dissolved in a solution containing ammonia water after the step of forming at least one nitride-based semiconductor layer, whereby the substrate can be removed. The conductive film may include an indium oxide layer, and the indium oxide layer is dissolved in a solution containing iron chloride after the step of forming at least one nitride-based semiconductor layer, whereby the substrate can be removed.

According to the present invention, the nitride-based semiconductor device includes a conductive film, a nitride-based semiconductor underlying layer, a nitride-based semiconductor layer of a first conductivity type, a light-emitting layer, and a nitride-based semiconductor layer of a second conductivity type formed in this order on a substrate.

The conductive film may include any of a metal, a metalloid, an alloy and a semiconductor. More specifically, the conductive film may include any of Mo, W, Ta, Nd, Al, Ti, Hf, Si, Ge, GaAs and GaP. Preferably, the conductive film has the reflectance of at least 50%. The conductive film may have a multi-layered structure.

The conductive film may include a nitride film, and the nitride film may have a resistivity high enough to function as a current blocking layer. The nitride-based semiconductor underlying layer may include InₓAl_{y}Ga_{1-x-y}N (0≦x, 0≦y, x+y<1).

In the present invention as described above, as the releasing layer is provided between the substrate and the nitride-based semiconductor layer, releasing of the substrate becomes easier, and then efficiency in producing the nitride-based semiconductor device can be increased. The releasing layer may be formed with a conductive film.

The first effect attained by forming the conductive film is that a nitride-based semiconductor layer having low dislocation density and good crystalline quality can be obtained by forming the conductive film of a metal, a conductive oxide or the like beforehand on the substrate and then forming the nitride-based semiconductor buffer layer thereon at a high temperature.

The second effect is that, in the case of fabricating a nitride-based semiconductor device including upper and lower electrodes, the sapphire substrate and the epitaxial nitride-based semiconductor stacked-layer structure can easily be separated by dissolving the conductive film through wet etching. Therefore, the yield rate of the devices can be improved as compared with the conventional method that uses lapping of the substrate, and the productivity of the devices can also be improved because it is possible to remove the substrate by the process taking short time.

The third effect is that, in the case of exposing the surface of the nitride-based semiconductor layer by separating the sapphire substrate through etching of the conductive film, the contact resistance of the electrode formed on the exposed surface becomes lower than in the case of not using the conductive film, and then it is possible to reduce the driving voltage of the resulting nitride-based semiconductor device. Although the mechanism of this phenomenon is not clear at this time, it may be considered as follows. In the case that a nitride-based semiconductor layer is formed directly on a sapphire substrate and the substrate is separated later by lapping as in the conventional method, a state of atoms on the exposed surface of the nitride-based semiconductor layer is possibly different from in the case that the substrate is separated utilizing the conductive film. Presumably because of protective effect and the like of the conductive film, there can be reduced undesirable interface energy levels that are liable to cause ohmic defects at the time of forming the contact electrode.

The fourth effect is attained in the case that the conductive film is not removed. When the light-emitting device includes a transparent substrate, light from the light-emitting layer propagates into the substrate too, and a considerable amount of light is emitted from the side surfaces of the transparent substrate. In the case that a conductive film having an appropriate reflectance is formed on the substrate and then the nitride-based semiconductor stacked-layer structure is formed thereon, the light is reflected by the conductive film and does not propagate into the substrate, whereby making it possible to improve the axial luminous intensity.

Further, when the substrate is not transparent, the non-transparent substrate in most cases has a low reflectance and thus light emitted from the light-emitting layer to the substrate side is considerably absorbed by the substrate. In the case that a conductive film having an appropriate reflectance is formed on the non-transparent substrate and the nitride-based semiconductor stacked-layer structure is formed thereon, light from the light-emitting layer is reflected by the conductive film and not absorbed by the substrate, whereby making it possible to improve the efficiency of taking light out of the light-emitting device.

In the case that the substrate is a semiconductor substrate, it is possible to fabricate a nitride-based semiconductor device including upper and lower electrodes without removing the conductive film. On the other hand, when there is not provided the conductive film, a barrier is formed at the interface between the semiconductor substrate and the nitride-based semiconductor layer because of the influence of interface energy levels, leading to higher driving voltage of the nitride-based semiconductor device. By forming the nitride-based semiconductor stacked-layer structure after forming the conductive film, however, it is possible to lower the driving voltage of the nitride-based semiconductor device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view illustrating a process of fabricating a portion of the nitride-based semiconductor device according to an embodiment of the present invention.

FIG. 2 is a schematic cross-sectional view illustrating a process of fabricating an Si substrate for lamination as a portion to be joined to the portion shown in FIG. 1.

FIG. 3 is a schematic cross-sectional view illustrating a process of fabricating a nitride-based semiconductor device by combining the portion of FIG. 1 with the portion of FIG. 2.

FIG. 4 is a schematic cross-sectional view of the nitride-based semiconductor device completed through further process steps after FIG. 3.

FIG. 5 is a schematic cross-sectional view of a nitride-based semiconductor device according to another embodiment of the present invention.

FIG. 6 is a schematic cross-sectional view of a nitride-based semiconductor device according to a further embodiment of the present invention.

### DESCRIPTION OF THE PREFERRED EMBODIMENTS

### Embodiment 1

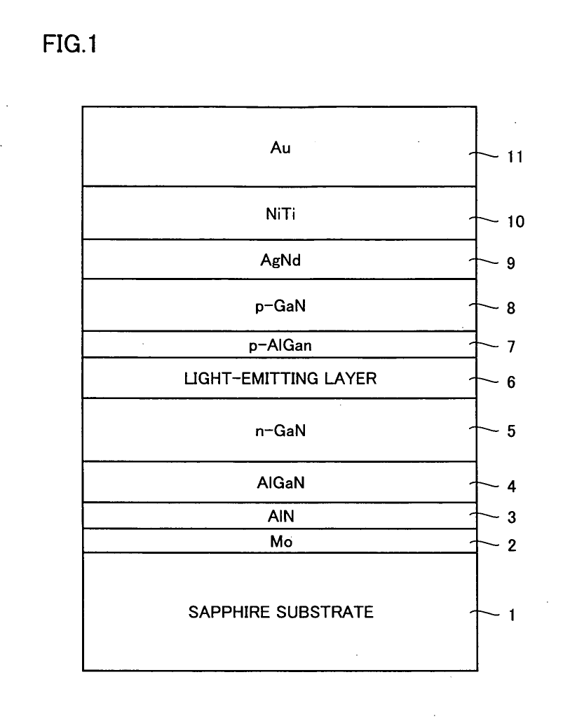

The schematic cross-sectional view of FIG. 1 shows a nitride-based compound semiconductor device fabricated according to Embodiment 1 of the present invention.

In the drawings of the present application, the same reference characters denote the same or corresponding portions.

In fabrication of the device shown in FIG. 1, an Mo layer 2 is first formed to a thickness of 5 nm on a sapphire substrate 1 by evaporation. Mo layer 2 is utilized later as a releasing layer for allowing easy removal of sapphire substrate 1. An Al layer (which is turned to AlN layer 3 later) is formed to a thickness of 3 nm on Mo layer 2 by evaporation. The wafer having the conductive film including the Mo layer and the Al layer on the sapphire substrate is introduced in an MOCVD (Metal Organic Chemical Vapor Deposition) apparatus.

The MOCVD furnace in which the wafer has been introduced is controlled to keep an internal pressure of 13.3 kPa. Under the pressure of 13.3 kPa, sapphire substrate 1 is heated from a room temperature to 1000° C. and held at 1000° C. for one minute. At this time, hydrogen is made to flow at 15 l/min. Then, flow of NH₃ is started at 100 ccm and, approximately at the same time, supply of TMG (trimethyl gallium) and TMA (trimethyl aluminum) is started. The flow rate of TMG is 51.3 μmol/min, the flow rate of TMA is 25.5 μmol/min, hydrogen is used as a carrier gas, and the total flow rate is set to 30 l/min. Consequently, an AlGaN buffer layer (underlying layer) 4 is grown to a thickness of about 0.7 μm in 60 minutes. At this time, the Al layer of 3 nm thickness that has been formed by evaporation is partially or entirely nitrided to become AlN layer 3. Preferably, semiconductor underlying layer 4 is deposited at a substrate temperature of at least 900° C. Although AlGaN underlying layer 4 is shown as an example in Embodiment 1, an underlying layer of InₓAl_{y}Ga_{1-x-y}N (0≦x, 0≦y, x+y<1) may be used in general.

Thereafter, supply of TMG and TMA into the furnace is stopped, NH₃ is made to flow at 100 ccm and hydrogen is made to flow such that the total flow attains to 30 l/min. In this state, the pressure in the furnace is changed from 13.3 kPa to 93.3 kPa. After the pressure becomes stable at 93.3 kPa, the flow rate of NH₃ is changed to 3.5 l/min, TMG is made to flow at 160 μmol/min, and SiH₄ is supplied at 70 ccm, so that an n-type GaN layer 5 is grown to a thickness of 4 μm. Such a conductivity type layer 5 is formed preferably with a substrate temperature being the same as or lower than that at which semiconductor underlying layer 4 is formed, in view of reducing the threading dislocations.

Then, the substrate temperature is lowered to 800° C., and there is grown a quantum well light-emitting layer 6 including at least one InGaN well layer and at least one GaN barrier layer. Thereafter, the substrate temperature is increased to 980° C., and there are grown a p-type AlGaN layer 7 and a p-type GaN layer 8 successively. After growth of these layers, the raw material supply for III-group elements is stopped, at the same time, the gas in the furnace is switched to N₂ gas containing 2% NH₃, and the substrate temperature is lowered.

The cooled wafer is taken out from the MOCVD furnace. On p-type GaN layer 8, an AgNd layer 9 of 100 nm thickness is formed as a contact electrode by sputtering, an NiTi layer 10 of 50 nm thickness is formed as a barrier metal layer threreon, and an Au layer 11 of 1 μm thickness is formed further thereon as a metal layer for lamination. Thereafter, the sapphire substrate is ground and lapped on its rear side, until the wafer comes to have a thickness of 100 μm. FIG. 1 shows, in a schematic cross-section, the nitride-based semiconductor device in a state fabricated through the process steps described above.

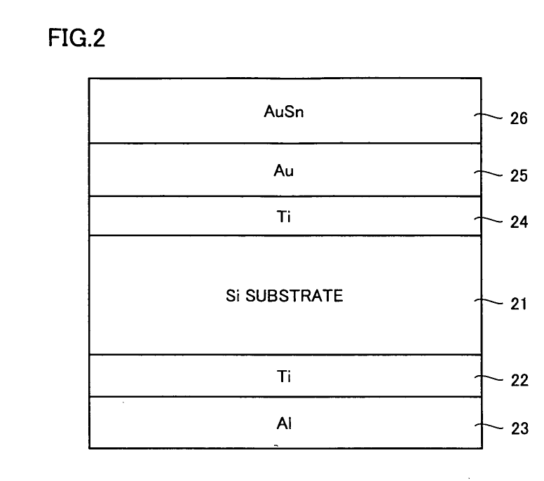

FIG. 2 shows, in a schematic cross-sectional view, an Si substrate for lamination to be bonded to the nitride-based semiconductor device shown in FIG. 1. In fabrication of the Si substrate for lamination shown in FIG. 2, a Ti layer 22 and an Al layer 23 are successively formed on the lower side of Si substrate 23, while a Ti layer 24, an Au layer 25 and an AuSn layer 26 are successively formed on the upper side of Si substrate 23.

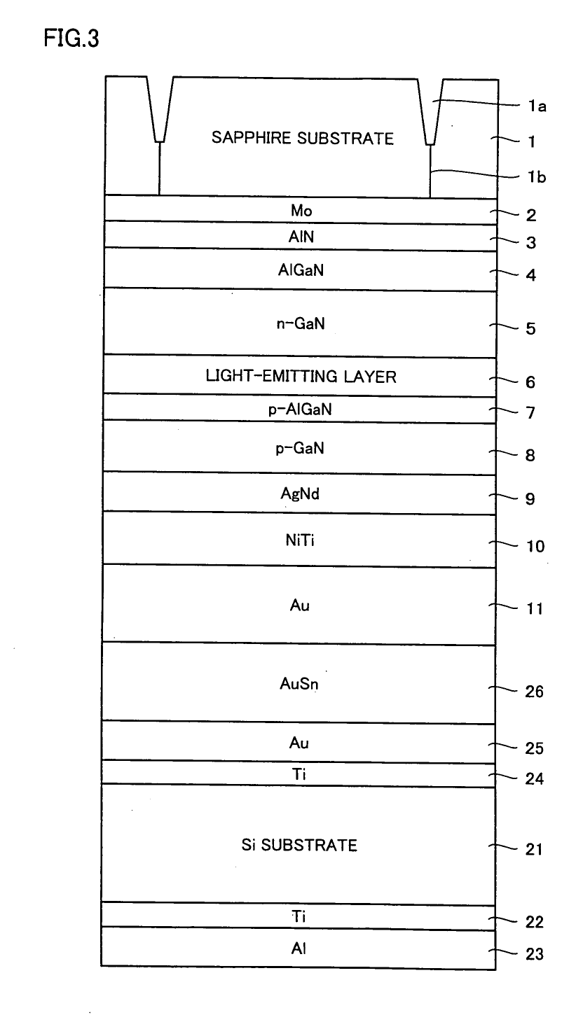

As shown in a schematic cross-section of FIG. 3, the nitride-based semiconductor device of FIG. 1 and the Si substrate for lamination of FIG. 2 are bonded to each other. Specifically, Au layer 11 of the nitride-based semiconductor device shown in FIG. 1 is placed facing and in contact with AuSn layer 25 of the Si substrate for lamination shown in FIG. 2, and these are joined to each other by thermal compression bonding. Then, by laser scribing on the free surface of sapphire substrate 1, trenches 1a or cracks 1b are formed at an interval corresponding to the chip size. Trenches 1a may reach Mo layer 2. When cracks 1b reach Mo layer 2, trenches 1a need not reach Mo layer 2.

Thereafter, the nitride-based semiconductor device of FIG. 3 is put in ammonia water, so that ammonia water permeates through cracks 1a to dissolve Mo layer 2 and, as a result, sapphire substrate 1 is separated. By using ammonia water as above, only Mo layer 2 can selectively be etched without dissolving the electrode layer or the metal layer for lamination other than the Mo layer 2, and sapphire substrate 1 can be separated easily. The layer exposed after removal of the sapphire substrate is AlN layer 3 that has initially been deposited as the Al layer by evaporation and nitrided thereafter.

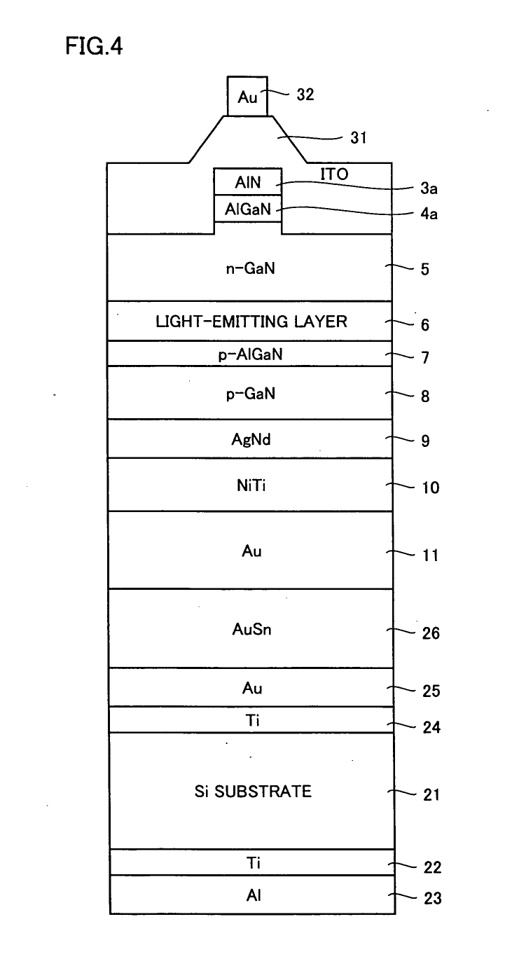

As shown in a schematic cross-sectional view of FIG. 4, while a part of AlN layer 3 is left by masking, the other part are dry-etched so as to partially expose n-type GaN layer 5. Thereafter, an ITO (indium tin oxide) layer 31 is formed as a transparent electrode, to cover the left part of AlN layer 3a and the exposed part of n-type GaN layer 5. On ITO layer 31, an Au pad electrode 32 is formed on an area that corresponds to the left part of AlN layer 3a. By such an arrangement, AlN layer 3a (high resistance layer) can function as a current blocking layer. Accordingly, current is not introduced just below pad electrode 32 and it is possible to reduce light emission loss caused by shielding with pad electrode 32. Finally, by chip division with laser scribing on the lower side of Si substrate 21, there are provided light-emitting device chips. That is, FIG. 4 schematically shows the cross-section of the light-emitting device chip fabricated in this manner.

The nitride-based semiconductor light-emitting device chip fabricated in this manner had an optical output of 30 mW with total luminous flux, and its forward voltage was 3V. In contrast, a nitride-based semiconductor device chip fabricated according to the conventional method without providing Mo layer 2 had an optical output of 7 mW, and its forward voltage was 3.4 V. That is, the present invention can realize significant increase of the optical output and reduction of the forward voltage in the nitride-based semiconductor light-emitting device chip. Further, the light-emitting device chip according to Embodiment 1 has not only high total luminous flux but also axial luminous intensity about ten times that of the light-emitting device chip fabricated according to the conventional method. Therefore, it is possible to improve characteristics of a side-light-emitting chip LED for a backlight.

### Embodiment 2

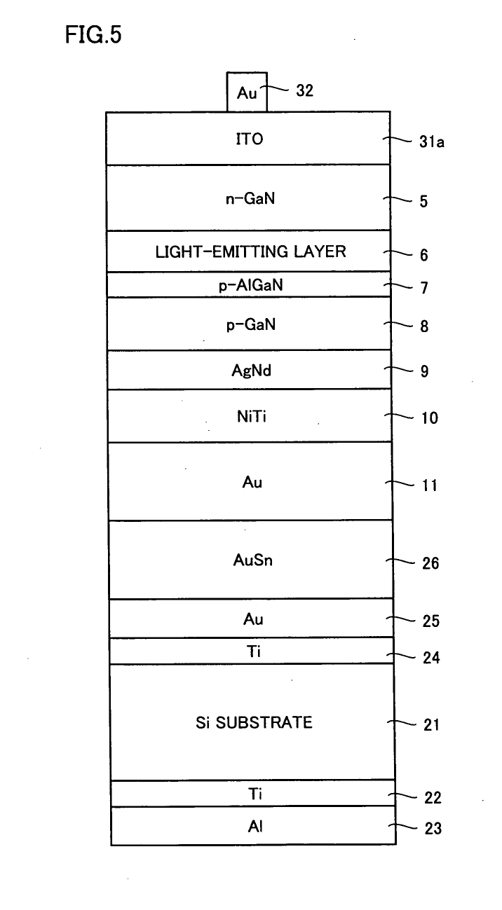

FIG. 5 shows, in a schematic cross-section, a nitride-based semiconductor device fabricated according to Embodiment 2 of the present invention. In Embodiment 2, an ITO layer (not shown) as a releasing layer is formed to a thickness of 80 nm in place of Mo layer 2 and AlN layer 3 of Embodiment 1, and AlGaN buffer layer 4 of Embodiment 1 is omitted.

The ITO releasing layer is dissolved with an iron chloride solution, whereby the sapphire substrate (not shown) is separated. Because of the use of iron chloride solution, only the ITO releasing layer can selectively be etched without dissolving the electrode layer or the metal layer for lamination other than the ITO releasing layer, and the sapphire substrate can be separated easily. When an ITO layer 31a is formed on n-type GaN layer 5 thus exposed, good contact conductance can be attained. The nitride-based semiconductor light-emitting device chip of Embodiment 2 fabricated in this manner had an optical output of 30 mW, and its forward voltage was 2.9V.

### Embodiment 3

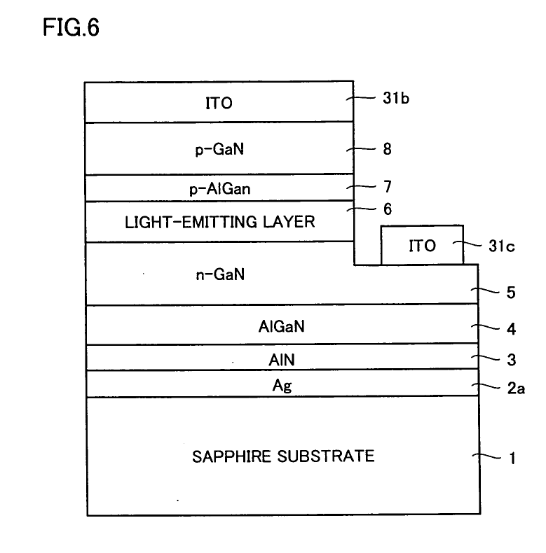

FIG. 6 shows, in a schematic cross-section, a nitride-based semiconductor device fabricated according to Embodiment 3 of the present invention. In Embodiment 3, an Ag layer 2a capable of functioning as a light reflecting layer is first formed to a thickness of 50 nm on sapphire substrate 1, and then an Al layer which is to be turned to AlN layer 3 later is formed to a thickness of 30 nm thereon. The wafer having the metal layers deposited on the sapphire substrate is introduced into the MOCVD apparatus. In Embodiment 3 also, a plurality of nitride-based semiconductor layers 4 to 8 are grown in a similar manner as in Embodiment 1 and thereafter the wafer is taken out from the MOCVD apparatus.

Next, an ITO layer 31b is formed as a p-electrode. A prescribed part of ITO 10, layer 31b is removed by etching, and at the removed part, a plurality of nitride-based semiconductor layers 6 to 8 are dry-etched, so that n-type GaN layer 5 is partially exposed. Then, on the exposed surface of n-type GaN layer 5, an ITO layer 31c is formed as an n-electrode. Thereafter, sapphire substrate 1 is ground and lapped on its rear side until the wafer comes to have a thickness of 100 μm, and the wafer is divided into chips by laser scribing.

The nitride-based semiconductor light-emitting device chip of Embodiment 3 fabricated in this manner had an optical output of 20 mW, and its forward voltage was 3.3 V. In Embodiment 3, light emitted form light-emitting layer 6 to the substrate 1 side is reflected by Ag layer 2a and taken out from the front surface of the chip. That is, in Embodiment 3, it is possible to reduce light that is transmitted to the sapphire substrate 1 side and emitted from the side surfaces of the chip, and thus the axial luminous intensity of the chip can be increased by about five times as compared with the chip fabricated according to the conventional method. Therefore, it is possible to improve characteristics of a side-light-emitting chip LED for a backlight.

When the nitride-based semiconductor device includes a light-reflecting conductive film formed on the substrate as in the case of Embodiment 3, it is preferable that the conductive film has a reflectance of at least 50%. As the conductive film having such a reflectance, it is possible to preferably use an Ag layer or an Al layer in particular.

Although examples in which an Mo layer and an Al layer, an ITO layer, or an Ag layer and an Al layer were formed on the sapphire substrate have been described in Embodiments 1 to 3 above, the releasing layer or the conductive film formed on the substrate are not limited to these, and it is also possible to use arbitrary metal, metalloid, alloy, or semiconductor suitable for the intended purpose. Specifically, the releasing layer or the conductive film formed on the substrate may include any of W, Ta, Nd, Al, Ti, Hf, Si, Ge, GaAs and GaP, and may also include, in place of ITO, another conductive oxide such as tin oxide or zinc oxide. Needless to say, the releasing layer or the conductive film formed on the substrate may have a multi-layered structure. The releasing layer or the conductive film on the substrate can easily be formed by suitably using evaporation, sputtering, plasma CVD and the like.

As described above, with the present invention, it is possible to improve various characteristics of the nitride-based semiconductor device and productivity thereof also.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of producing a nitride-based semiconductor device, comprising the steps of:
forming a releasing layer on a substrate for facilitating separation of the substrate; and
forming at least one nitride-based semiconductor layer on said releasing layer.

2. A method of producing a nitride-based semiconductor device, comprising the steps of:
forming at least one conductive film on a substrate; and
forming at least one nitride-based semiconductor layer on said conductive layer.

3. The method of forming a nitride-based semiconductor device according to claim 2, wherein
said conductive film includes any of a metal, a metalloid, an alloy, or a semiconductor.

4. The method of forming a nitride-based semiconductor device according to claim 3, wherein
said conductive film includes any of Mo, W, Ta, Nd, Al, Ti, Hf, Si, Ge, GaAs, and GaP.

5. The method of forming a nitride-based semiconductor device according to claim 2, wherein
said conductive film has a reflectance of at least 50%.

6. The method of forming a nitride-based semiconductor device according to claim 5, wherein
said conductive film is made of a metal or an alloy containing Ag or Al.

7. The method of forming a nitride-based semiconductor device according to claim 2, wherein
said conductive film is made of a conductive metal oxide.

8. The method of forming a nitride-based semiconductor device according to claim 7, wherein
said conductive metal oxide includes indium oxide.

9. The method of forming a nitride-based semiconductor device according to claim 2, wherein
said conductive film is formed to have a multi-layered structure.

10. The method of forming a nitride-based semiconductor device according to claim 2, wherein
said conductive film is formed by evaporation, sputtering or plasma CVD.

11. The method of forming a nitride-based semiconductor device according to claim 2, wherein
in said step of forming at least one nitride-based semiconductor layer, a nitride-based semiconductor underlying layer, a nitride-based semiconductor layer of a first conductivity type, a light-emitting layer, and a nitride-based semiconductor layer of a second conductivity type are deposited successively.

12. The method of forming a nitride-based semiconductor device according to claim 11, wherein
said nitride-based semiconductor underlying layer is deposited at a temperature of at least 900° C.

13. The method of forming a nitride-based semiconductor device according to claim 11, wherein
said nitride-based semiconductor layer of the first conductivity type is deposited at a temperature not higher than that for deposition of said nitride-based semiconductor underlying layer.

14. The method of forming a nitride-based semiconductor device according to claim 11, wherein
a metal layer included in said conductive film is reacted to form a nitride film, and the nitride film is processed to a shape of a current blocking layer.

15. The method of forming a nitride-based semiconductor device according to claim 11, wherein
said nitride-based semiconductor underlying layer is formed of InₓAl_{y}Ga_{1-x-y}N (0≦x, 0≦y, x+y<1).

16. The method of forming a nitride-based semiconductor device according to claim 2, wherein
said conductive film includes an Mo layer, and said Mo layer is dissolved in a solution containing ammonia water after said step of forming at least one nitride-based semiconductor layer, whereby said substrate is removed.

17. The method of forming a nitride-based semiconductor device according to claim 2, wherein
said conductive film includes an indium oxide layer, and said indium oxide layer is dissolved in a solution containing iron chloride after said step of forming at least one nitride-based semiconductor layer, whereby said substrate is removed.

18. A nitride-based semiconductor device, comprising
a conductive film, a nitride-based semiconductor underlying layer, a nitride-based semiconductor layer of a first conductivity type, a light-emitting layer, and a nitride-based semiconductor layer of a second conductivity type formed in this order on a substrate.

19. The nitride-based semiconductor device according to claim 18, wherein
said conductive film includes any of a metal, a metalloid, an alloy and a semiconductor.

20. The nitride-based semiconductor device according to claim 19, wherein
said conductive film includes any of Mo, W, Ta, Nd, Al, Ti, Hf, Si, Ge, GaAs, and GaP.

21. The nitride-based semiconductor device according to claim 18, wherein
said nitride-based semiconductor underlying layer includes InₓAl_{y}Ga_{1-x-y}N (0≦x, 0≦y, x+y<1).

22. The nitride-based semiconductor device according to claim 18, wherein
said conductive film has a reflectance of at least 50%.

23. The nitride-based semiconductor device according to claim 18, wherein
said conductive film has a multi-layered structure.

24. The nitride-based semiconductor device according to claim 18, wherein
said conductive film includes a nitride film, and the nitride film has a sufficiently high resistivity to function as a current blocking layer.
